(19) United States
(12) Patent Application Publication
(10) Pub. No.: US 2016/0291077 A1
(43) Pub. Date: Oct. 6, 2016

(54) PROBLEM DETECTION IN CABLE SYSTEM

(71) Applicant: PHILIPS LIGHTING HOLDING B.V., Eindhoven (NL)

(72) Inventors: HONGXIN CHEN, EINDHOVEN (NL); HONG CHEN, EINDHOVEN (NL)

(21) Appl. No.: 15/036,402

(22) PCT Filed: Nov. 11, 2014
(86) PCT No.: PCT/EP2014/074219

§ 371 Date: May 12, 2016

(30) Foreign Application Priority Data
Nov. 13, 2013 (CN) PCT/CN2013/001381
Dec. 3, 2013 (EP) 13195420.8

(51) Int. Cl. G01R 31/11

(52) U.S. Cl. CPC G01R 31/11

(57) ABSTRACT

Devices (1) for detecting problems in cable systems (2) comprising cables (20-24) and loads (31-34) are provided with injectors (11, 12) for injecting first investigation signals into the cables (20-24), receivers (13) for receiving first reflection signals comprising first reflections of the first investigation signals from the cables (20-24), and processors (14). The processors (14) convert the first reflection signals into reflection values and determine differences between the reflection values and reference values. A firstly occurring significant difference of the differences is indicative for the problem, and a moment in time of the firstly occurring significant difference is indicative for a location of the problem. Previously received reflection signals comprising reflections from previously injected investigation signals that have been injected at moments in time at which there were no problems in the cable system (2) may be converted into the reference values.

### FIELD OF THE INVENTION

The invention relates to a device for detecting a problem in a cable system comprising a cable and a plurality of loads coupled to the cable. The invention further relates to a collection system comprising a device, to a method for detecting a problem in a cable system, to a computer program product for performing the steps of the method, and to a medium for storing and comprising the computer program product.

Examples of such a cable system are cables coupled to loads for feeding the loads. Examples of such loads are lamps.

### BACKGROUND OF THE INVENTION

A use of a travelling wave for finding a fault location in a transmission line is of common general knowledge.

### SUMMARY OF THE INVENTION

It is an object of the invention to provide an improved device. Further objects of the invention are to provide a collection system, an improved method, a computer program product and a medium.

According to a first aspect, a device is provided for detecting a problem in a cable system comprising a cable and a plurality of loads coupled to the cable, the device comprising
an injector for injecting a first investigation signal into the cable,
a receiver for receiving a first reflection signal from the cable, the first reflection signal comprising first reflections of the first investigation signal, and
a processor for converting the first reflection signal into reflection values and for determining differences between the reflection values and reference values, a firstly occurring difference of the differences when being equal to or larger than a threshold value being indicative for the problem, and a moment in time of the firstly occurring difference being indicative for a location of the problem.

An injector injects a first investigation signal into a cable coupled to loads. Usually, the cable comprises a main part (a stem part) and branch parts. Each branch part connects a load to the main part. Usually, the respective branch parts are connected to the main part at respective locations. Without a problem being present, the first investigation signal will be reflected at a start of the branch part as well as at an end of the branch part, which end is connected to a load. In case a problem is present, such as a malfunctioning load or a missing load, the investigation signal will, at the end of the branch part, be reflected differently from before. In case another problem is present, such as a broken/short-circuited branch part or a (partly) missing branch part or a broken/short-circuited main part, the investigation signal will, at a location of this problem, be reflected (for the first time or differently than before).

The problem could also be illegal appliance connected to the main part of the cable. The illegal appliance connected to the main part of the cable will cause investigation signal to be reflected at the connection point.

Preferrably, an inductor could be coupled between the each loads and its the branch cable, or between the each branch cable and the main cable.

A receiver receives a first reflection signal from the cable. The first reflection signal comprises first reflections of the first investigation signal. A processor converts the first reflection signal into reflection values and determines differences between the reflection values and reference values. The reference values are for example expected reflection values which have been determined (i.e. calculated) before, for a situation wherein no problem is occurring. A firstly occurring difference between the reflection values and reference values, which firstly occurring difference should be equal to or larger than a threshold value, will be indicative for a problem. A moment in time of the firstly occurring difference with respect to a moment in time of an injection of the first investigation signal will be indicative for a location of the problem. In other words, a duration of a time-interval situated between the moment in time of the firstly occurring difference and the moment in time of the injection of the first investigation signal will be indicative for the location of the problem. As a result, a travelling wave is used for finding a fault location in a transmission line, whereby relevant reflections and irrelevant reflections are easily distinguished from each other.

An embodiment of the device is defined by the processor being arranged to convert a previously received reflection signal comprising reflections from a previously injected investigation signal that has been injected at a moment in time at which there was no problem in the cable system into the reference values. Preferably, the reference values are for example expected reflection values which have been determined (i.e. measured) before, for a situation wherein no problem is occurring.

An embodiment of the device is defined by the injector being arranged to inject a second investigation signal after the first investigation signal into the cable, the receiver being arranged to receive a second reflection signal from the cable, the second reflection signal comprising second reflections of the second investigation signal, the processor being arranged to convert the second reflection signal into the reflection values, and the processor being arranged to convert previously received reflection signals comprising reflections from previously injected investigation signals that have been injected at moments in time at which there were no problems in the cable system into the reference values. Preferably, the processor converts the first and second reflection signals into first and second reflection values and averages the first and second reflection values to get mean reflection values, to eliminate noise etc. Further, preferably, the processor converts first and second previously received reflection signals comprising first and second reflections from the first and second previously injected investigation signals that have been injected at moments in time at which there were no problems in the cable system into first and second reference values and averages the first and second reference values to get mean reference values to eliminate noise etc. As a result, the processor determines differences between the mean reflection values and the mean reference values etc. whereby noise is eliminated.

An embodiment of the device is defined by the processor being arranged to determine the differences between the reflection values and the reference values by comparing a respective reflection value with a respective reference value. A first possibility to determine the differences is comparing the (mean) reflection values and the (mean) reference values one by one. In other words, per moment in time, a (mean) reflection value is compared with a corresponding (mean) reference value.

An embodiment of the device is defined by the processor being arranged to determine the differences between the reflection values and the reference values by inserting one or more reflection values into a first function and calculating a first result and inserting one or more reference values into a second function and calculating a second result and by comparing the first and second results with each other. A second possibility to determine the differences is calculating function results and comparing them.

An embodiment of the device is defined by the processor being arranged to determine the differences between the reflection values and the reference values by inserting one or more reflection values and one or more reference values into a third function and calculating a third result and by comparing the third result with the threshold value. A third possibility to determine the differences is calculating a function result and comparing it with the threshold value.

The use of the first and second functions on the one hand and the use of the third function on the other hand may be advantageously combined.

An embodiment of the device is defined by the injector comprising a generator for generating a first pulse signal, the first investigation signal comprising the first pulse signal. A first possibility to realize an injection of a first investigation signal is generating a first pulse signal having an amplitude larger than or additional to an amplitude of a feeding signal for feeding the loads via the cable at a moment in time at which the feeding signal is present or having an amplitude smaller or larger than or equal to the amplitude of the feeding signal at a moment in time at which the feeding signal is not present. Of course, in case the first investigation signal is injected at a moment in time at which the feeding signal is (not) present, the previously injected investigation signal to determining the reference values should also have been injected at a moment in time at which the feeding signal is (not) present.

An embodiment of the device is defined by the injector comprising a switch for switching a feeding signal for feeding the loads via the cable. A second possibility to realize an injection of a first investigation signal is switching a feeding signal for feeding the loads via the cable. Such switching will result in a first pulse signal being injected into the cable.

An embodiment of the device is defined by further comprising
a controller for detecting a phase-angle of the feeding signal and for in response to a detection result controlling the switch for switching-off the feeding signal at a pre-defined phase angle of the feeding signal. When switching off the feeding signal at a pre-defined phase angle of the feeding signal, a first pulse signal will be injected into the cable.

An embodiment of the device is defined by further comprising
a controller for controlling the switch for interrupting the feeding signal for a first time-interval shorter than 0.1 second. When interrupting the feeding signal for a first time-interval shorter than 0.1 second (preferably shorter than 0.01 second, more preferably shorter than 0.001 or 0.0001 second) for example once per second time-interval longer than 1 second (preferably longer than 10 seconds, more preferably longer than 100 or 1000 seconds), a first pulse signal will each time be injected into the cable, and its first reflections can be studied.

A controller may partly or entirely form part of a processor, or not, and a processor may partly or entirely form part of a controller, or not.

According to a second aspect, a collection system is provided comprising the device as defined above and further comprising a cable and/or a load and/or a source.

An embodiment of the collection system is defined by comprising the load in the form of a lamp. Examples of such a lamp are streetlamps (such as light emitting diodes).

According to a third aspect, a method is provided for detecting a problem in a cable system comprising a cable and a plurality of loads coupled to the cable, a first investigation signal being injected into the cable, a first reflection signal being received from the cable, the first reflection signal comprising first reflections of the first investigation signal, the method comprising a step of converting the first reflection signal into reflection values and a step of determining differences between the reflection values and reference values, a firstly occurring difference of the differences when being equal to or larger than a threshold value being indicative for the problem, and a moment in time of the firstly occurring difference being indicative for a location of the problem.

According to a fourth aspect, a computer program product is provided for performing the steps of the method as defined above.

According to a fifth aspect, a medium is provided for storing and comprising the computer program product as defined above.

An insight is that a travelling wave can be used for finding a fault location in a transmission line. A basic idea is that differences between reflection values and reference values can be used to indicate a problem and its location and need to be determined.

A problem to provide an improved device has been solved. A further advantage is that a firstly occurring difference between the reflection values and the reference values forms a clear and present indication for the problem as well as its location.

These and other aspects of the invention will be apparent from and elucidated with reference to the embodiments described hereinafter.

### BRIEF DESCRIPTION OF THE DRAWINGS

In the drawings:

FIG. 1 shows an embodiment of a device coupled to a cable system,

FIG. 2 shows a pulse signal and its reflections,

FIG. 3 shows two failure situations,

FIG. 4 shows a non-failure situation and ten failure situations,

FIG. 5 shows another non-failure situation and ten failure situations,

FIG. 6 shows a flow chart,

FIG. 7 shows another embodiment of a device coupled to a cable system,

FIG. 8 shows a feeding signal being switched off,

FIG. 9 shows four failure situations,

FIG. 10 shows a feeding signal being switched off and a failure situation, and

FIG. 11 shows another embodiment of a device coupled to a cable system.

### DETAILED DESCRIPTION OF EMBODIMENTS

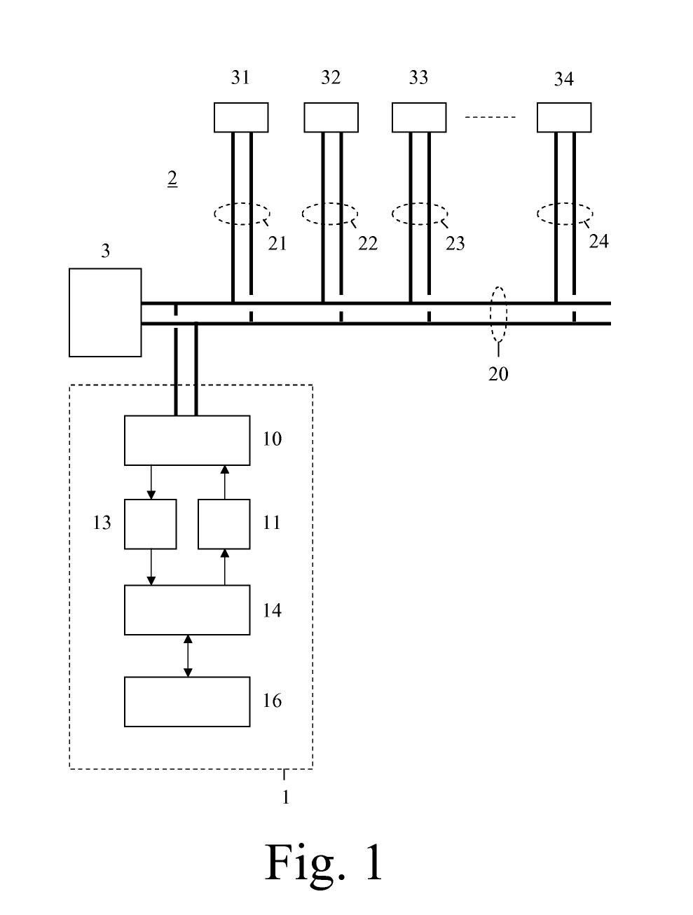

In the FIG. 1, an embodiment of a device 1 coupled to a cable system 2 is shown. The cable system 2 comprises a cable 20-24, a plurality of loads 31-34 and a source 3. The cable 20-24 comprises a main part 20 (a stem part 20, or main cable 20) and branch parts 21-24 (branch cable 21-24). The main part 20 is coupled to the respective loads 31-34 via the respective branch parts 21-24. The device 1 comprises a cable-interface 10 coupled to the cable 20-24 (or to the source 3) and an injector 11 coupled to the cable-interface 10 for injecting a first investigation signal into the cable 20-24. The injector 11 is here in the form of a generator 11 for generating a first investigation signal in the form of a first pulse signal. The device 1 further comprises a receiver 13 coupled to the cable-interface 10 for receiving a first reflection signal from the cable 20-24. The first reflection signal comprises first reflections of the first investigation signal.

The device 1 further comprises a processor 14 coupled to the injector 11 and the receiver 13 for converting the first reflection signal into reflection values and for determining differences between the reflection values and reference values. A firstly occurring difference of the differences when being equal to or larger than a threshold value will be indicative for a problem in the cable system 2. A moment in time of the firstly occurring difference will be indicative for a location of the problem. The device 1 may further comprise a man-machine-interface 16 coupled to the processor 14 for interaction with a person. The cable-interface 10 may be left out in case the injector 11 and the receiver 13 can communicate more directly with the cable 20-24.

Preferably, the processor 14 is arranged to convert a previously received reflection signal comprising reflections from a previously injected investigation signal into the reference values. The previously injected investigation signal has been injected at a moment in time at which there was no problem in the cable system 2. In that case, the reference values are for example expected reflection values which have been determined before, for a situation wherein no problem is occurring.

Preferably, the injector 11 is arranged to inject a second investigation signal after the first investigation signal into the cable 20-24, and the receiver 13 is arranged to receive a second reflection signal from the cable 20-24. The second reflection signal comprises second reflections of the second investigation signal. The processor 14 is arranged to convert the second reflection signal into the reflection values, and to convert previously received reflection signals comprising reflections from previously injected investigation signals into the reference values. These previously injected investigation signals have been injected at moments in time at which there were no problems in the cable system 2. In that case, the processor 14 converts the first and second reflection signals into first and second reflection values and averages the first and second reflection values to get mean reflection values. The processor 14 further converts first and second previously received reflection signals comprising first and second reflections from the first and second previously injected investigation signals into first and second reference values and averages the first and second reference values to get mean reference values. This all is for example done to eliminate noise. As a result, the processor 14 determines differences between the mean reflection values and the mean reference values etc.

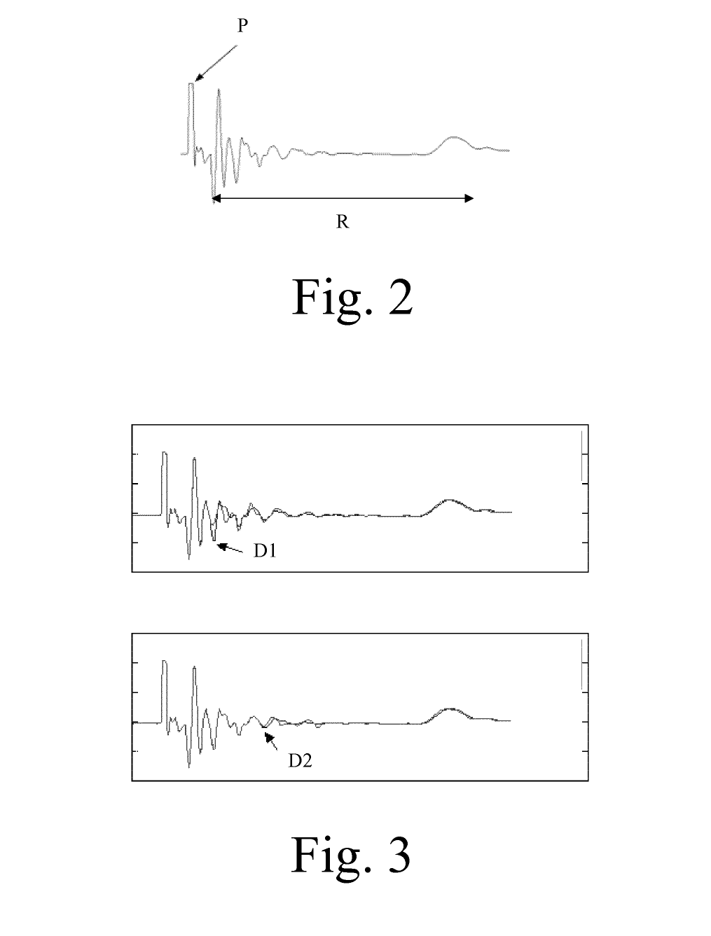

In the FIG. 2, a pulse signal P and its reflections R are shown (vertical axis: amplitude, for example voltage amplitude, horizontal axis: time). Clearly, one first pulse signal P when injected into the cable 20-24 results in a group of first reflections R coming back. Usually, the respective branch parts 21-24 are connected to the main part 20 at respective locations. Without a problem being present, the first investigation signal here comprising the first pulse signal P will be reflected at a start of each branch part 21-24 as well as at an end of each branch part 21-24, which end is connected to a load 31-34. In case a problem is present, such as a malfunctioning load 31-34 or a missing load 31-34, the investigation signal will, at the end of the branch part 21-24, be reflected differently from before. In case a problem is present, such as a broken/short-circuited branch part 21-24 or a (partly) missing branch part 21-24 or a broken/short-circuited main part 20, the investigation signal will, at a location of this problem, be reflected (for the first time or differently than before).

In the FIG. 3, two failure situations are shown (vertical axis: amplitude, for example voltage amplitude, horizontal axis: time). In the upper sketch, the load 32 is malfunctioning or missing. As a result, at a moment in time defined by a starting point of difference D1, the reflection values (amplitudes of the reflection signal at subsequent moments in time) and the reference values (amplitudes of the previously received reflection signal at subsequent moments in time when there was no problem in the cable system 2) start to be different from each other. In the lower sketch, the load 34 is malfunctioning or missing. As a result, at a moment in time defined by a starting point of difference D2, the reflection values and the reference values start to be different from each other. The firstly occurring difference D1/D2 will be indicative for a problem. The speed of the investigation/reflection signal multiplied by a duration of a time-interval situated between an injection of the investigation signal and a firstly occurring difference D1/D2 and divided by two will be indicative for a location of the problem. In other words, a moment in time of the firstly occurring difference D1/D2 will be indicative for a location of the problem.

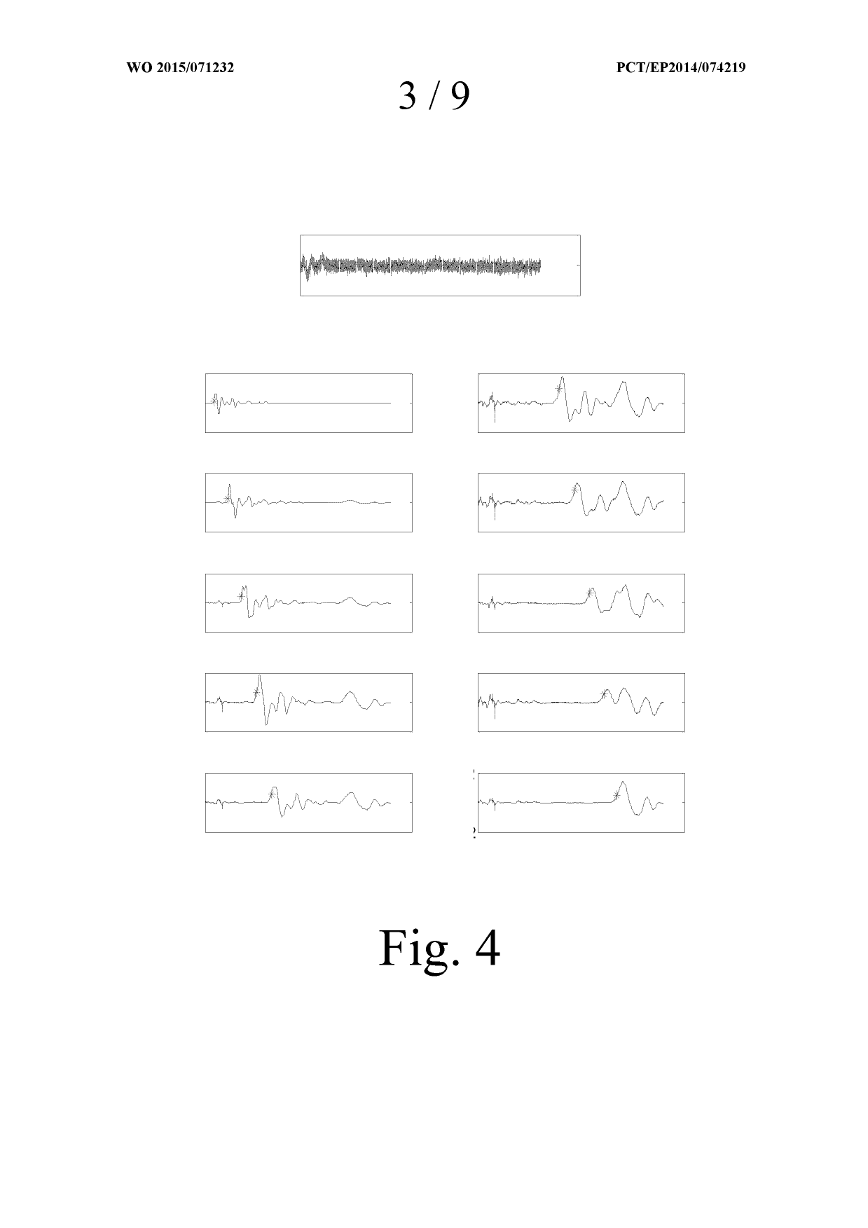

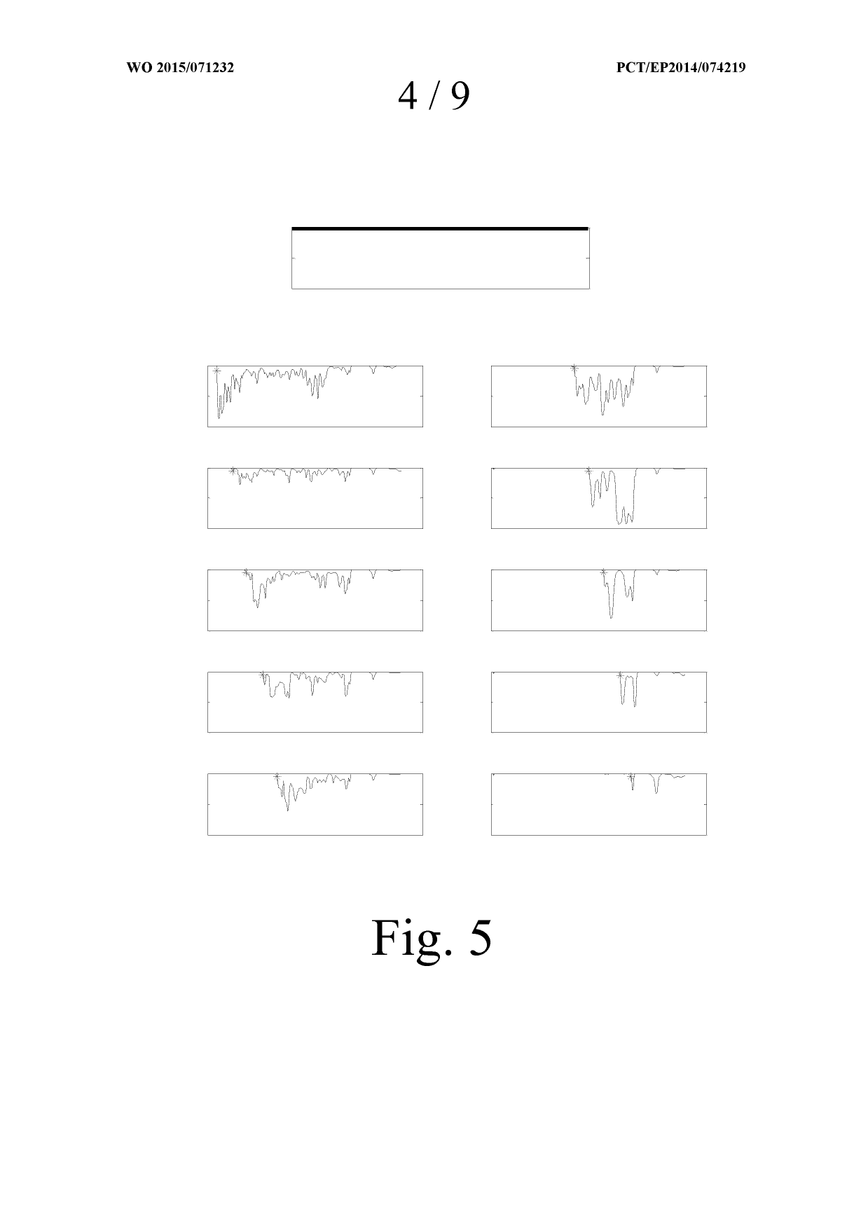

The processor 14 can determine the differences between the reflection values and the reference values by comparing a respective reflection value with a respective reference value, and/or by inserting one or more reflection values into a first function and calculating a first result and inserting one or more reference values into a second function and calculating a second result and by comparing the first and second results with each other, and/or by inserting one or more reflection values and one or more reference values into a third function and calculating a third result and by comparing the third result with the threshold value, as further discussed at the hand of the FIGS. 4 and 5.

In the FIG. 4, a non-failure situation and ten failure situations are shown (vertical axis: amplitude, for example voltage amplitude, horizontal axis: time). In the upper sketch, there is a non-failure situation. In the left column, in a downward direction, the first load 31 is malfunctioning or missing, the second load 32 is malfunctioning or missing, the third load 33 is malfunctioning or missing, the fourth load 34 is malfunctioning or missing, and a fifth load is malfunctioning or missing. In the right column, in a downward direction, respective sixth to tenth loads are malfunctioning or missing. Each time, a star is a firstly occurring (significant) difference between the reflection values and the reference values. So, at a moment in time defined by a star, the reflection values and the reference values start to be different from each other. In this case, the differences between the reflection values and the reference values are determined by comparing a respective reflection value with a respective reference value, by low pass filtering the differences, and by comparing the low pass filtered differences with the threshold value, such as for example x times a variance of a difference vector of S_{new}, and S_{ref}, wherein S_{new} is a vector of the reflection values and S_{ref} is a vector of the reference values, and wherein x=3, without having excluded other values for x.

Alternatively, the differences between the reflection values and the reference values can be determined by inserting one or more reflection values into a first (averaging) function and calculating a first (mean) result and inserting one or more reference values into a second (averaging) function and calculating a second (mean) result and by comparing the first and second (mean) results with each other to find out from which moment in time they are significantly different etc.

In the FIG. 5, another non-failure situation and ten failure situations are shown (vertical axis: amplitude, for example voltage amplitude, horizontal axis: time). In the upper sketch, there is a non-failure situation. In the left column, in a downward direction, the first load 31 is malfunctioning or missing, the second load 32 is malfunctioning or missing, the third load 33 is malfunctioning or missing, the fourth load 34 is malfunctioning or missing, and a fifth load is malfunctioning or missing. In the right column, in a downward direction, respective sixth to tenth loads are malfunctioning or missing. Each time, a star is a firstly occurring (significant) difference between the reflection values and the reference values. So, at a moment in time defined by a star, the reflection values and the reference values start to be different from each other. In this case, the differences between the reflection values and the reference values are determined through normalized cross correlation. In the non-failure situation, the normalized cross correlation is equal to one. A window is used to slide over the reflection values and the reference values. A width of the window is for example 50 nsec. Each time, the window is slid by one value point, and for each position of the window a third result of a third function is calculated. The third function is for example a product of C_{new}, and C_{ref} divided by a product of absolute values of C_{new}, and C_{ref} with C_{new}, being a vector of the reflection values positioned within the window and C_{ref} being a vector of the reference values positioned within the window. The third result is compared with the threshold value etc.

Alternatively, the differences between the reflection values and the reference values can be determined by considering the window over the reflection values to be a first function and by considering the window over the reference values to be a second function, wherein first and second function results are compared with each other through normalized cross correlation to find out from which moment in time they are significantly different etc.

In the FIG. 4, some failure situations with a failure at a larger distance have got another amplitude-scale for showing more details than some failure situations with a failure at a closer distance. In the FIG. 5, all failure situations have got a same amplitude-scale. Experiments have proven that both ways function well and result in finding relatively similar distances (<±5%) for a same failure.

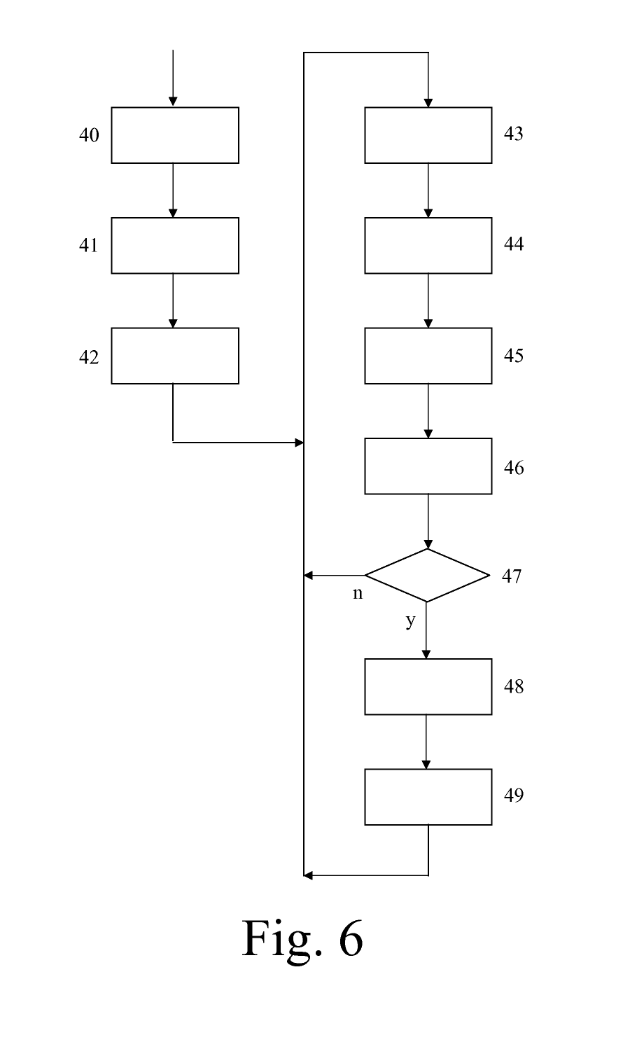

In the FIG. 6, a flow chart is shown, wherein the following blocks have the following meaning:

Block 40: Inject a pulse signal n times in a situation wherein there is no problem.
Block 41: Record for each case of the n times the reference values.
Block 42: Create mean reference values by averaging the reference values.
Block 43: Inject a pulse signal m times in a situation to be investigated.
Block 44: Record for each case of the m times the reflection values.
Block 45: Create mean reflection values by averaging the reflection values.
Block 46: Compare the mean reflection values with the mean reference values.
Block 47: Is there a significant difference? If no, go to block 43. If yes, go to block 48.
Block 48: Determine the firstly occurring difference of the significant differences.
Block 49: Determine a location of the problem. Go to block 43.

It is to be noted that the in the above embodiment, the feeding signal such as for example a voltage signal for feeding the loads 31-33 via the cable 20-23 may exist or may not exist, i.e. the sources 3 could be on or could be off. In case of the source 3 is on, the injected first pulse signal might cause interference to the normal work of the loads 31-33. So in this case, preferably, the first pulse signal is injected to the main cable through a capacitor.

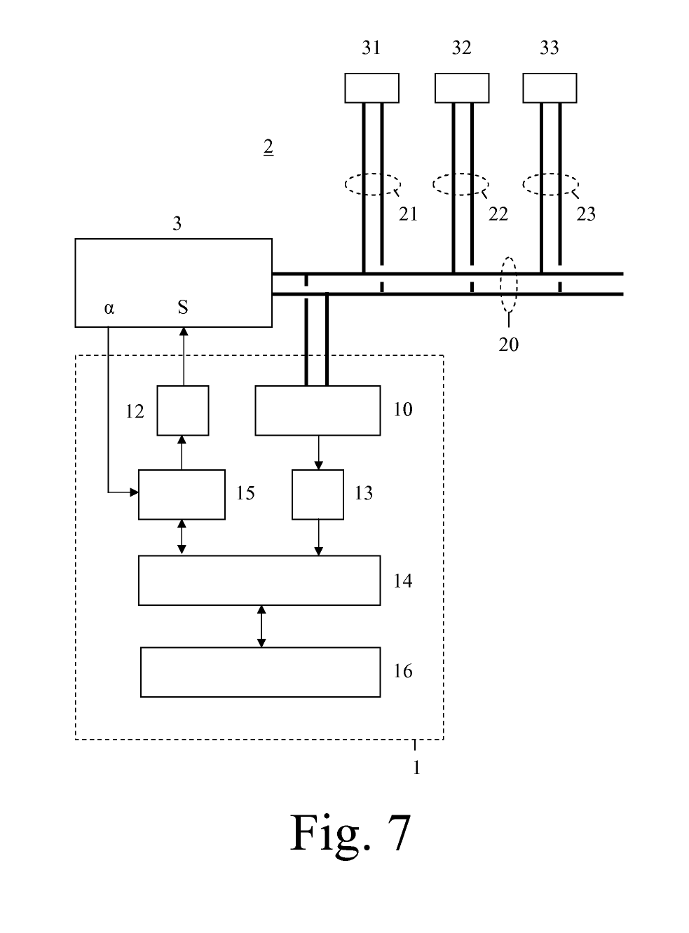

In the FIG. 7, another embodiment of a device 1 coupled to a cable system 2 is shown. The cable system 2 comprises a cable 20-23, a plurality of loads 31-33 and a source 3. The cable 20-23 comprises a main part 20 (a stem part 20) and branch parts 21-23. The main part 20 is coupled to the respective loads 31-33 via the respective branch parts 21-23. The device 1 comprises a cable-interface 10 coupled to the cable 20-23 (or to the source 3) and a receiver 13 coupled to the cable-interface 10 for receiving a first reflection signal from the cable 20-24. The first reflection signal comprises first reflections of a first investigation signal. The device 1 further comprises an injector 12 coupled to an input S of the source 3 (or to a power switch somewhere in the cable 20-23) for injecting a first investigation signal into the cable 20-23. The injector 12 is here in the form of a switch 12 for switching a feeding signal such as for example a voltage signal for feeding the loads 31-33 via the cable 20-23.

The device 1 further comprises a processor 14 coupled to the receiver 13 for converting the first reflection signal into reflection values and for determining differences between the reflection values and reference values. A firstly occurring difference of the differences when being equal to or larger than a threshold value will be indicative for a problem in the cable system 2. A moment in time of the firstly occurring difference will be indicative for a location of the problem. The device 1 may further comprise a man-machine-interface 16 coupled to the processor 14 for interaction with a person. The cable-interface 10 may be left out in case the receiver 13 can communicate more directly with the cable 20-23 (or with the source 3).

The device 1 further comprises a controller 15 coupled to the processor 14 and to the switch 12 for controlling the switch 12. The controller 15 may be coupled to an output a of the source 3 for detecting a phase-angle of the feeding signal and for in response to a detection result controlling the switch 12 for switching-off the feeding signal at a pre-defined phase angle of the feeding signal. When switching off the feeding signal at a pre-defined phase angle of the feeding signal, a first pulse signal will be injected into the cable etc. Or the controller 15 may be arranged for controlling the switch 12 for interrupting the feeding signal for a first time-interval shorter than 0.1 second such as for example 1 μsec. for example once per second time-interval longer than 1 second such as for example 1 hour. When interrupting the feeding signal shortly, a first pulse signal will each time be injected into the cable, and its first reflections can be studied. The controller 15 may partly or entirely form part of the processor 14, and vice versa.

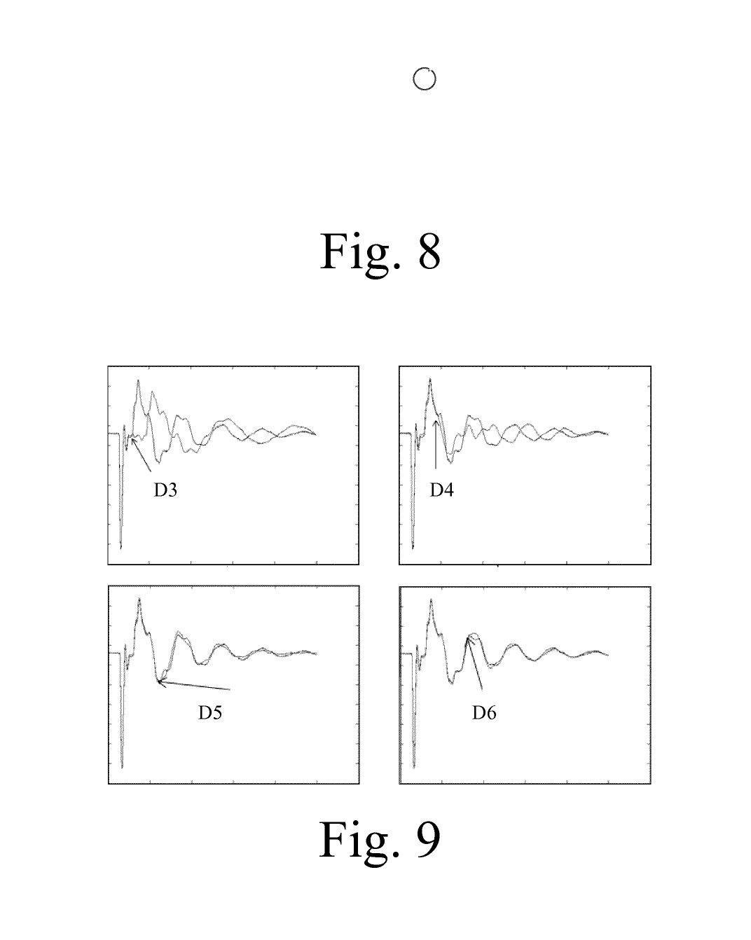

In the FIG. 8, a feeding signal being switched off is shown (vertical axis: amplitude, for example voltage amplitude, horizontal axis: time). The circle at a moment of switching off is shown in greater detail in the FIG. 9.

In the FIG. 9, four failure situations are shown (vertical axis: amplitude, for example voltage amplitude, horizontal axis: time). In the upper left sketch, a first load 31 is malfunctioning or missing. As a result, at a moment in time defined by a starting point of difference D3, the reflection values (amplitudes of the reflection signal at subsequent moments in time) and the reference values (amplitudes of the previously received reflection signal at subsequent moments in time when there was no problem in the cable system 2) start to be different from each other. In the upper right sketch, a second load 32 is malfunctioning or missing. As a result, at a moment in time defined by a starting point of difference D4, the reflection values and the reference values start to be different from each other. In the lower left sketch, a third load 33 is malfunctioning or missing. As a result, at a moment in time defined by a starting point of difference D5, the reflection values and the reference values start to be different from each other. In the lower right sketch, a fourth load is malfunctioning or missing. As a result, at a moment in time defined by a starting point of difference D6, the reflection values and the reference values start to be different from each other.

The firstly occurring difference D3−D6 will be indicative for a problem. The speed of the investigation/reflection signal multiplied by a duration of a time-interval situated between an injection of the investigation signal and a firstly occurring difference D3−D6 and divided by two will be indicative for a location of the problem. In other words, a moment in time of the firstly occurring difference D3−D6 will be indicative for a location of the problem.

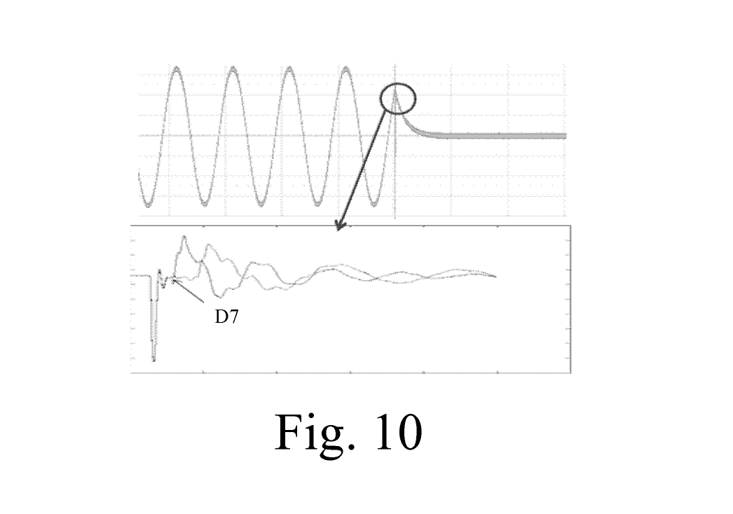

In the FIG. 10, a feeding signal being switched off (upper sketch, vertical axis: amplitude, for example voltage amplitude, horizontal axis: time) and a failure situation (lower sketch, vertical axis: amplitude, for example voltage amplitude, horizontal axis: time) are shown. At a moment in time defined by a starting point of difference D7, the reflection values (amplitudes of the reflection signal at subsequent moments in time) and the reference values (amplitudes of the previously received reflection signal at subsequent moments in time when there was no problem in the cable system 2) start to be different from each other etc.

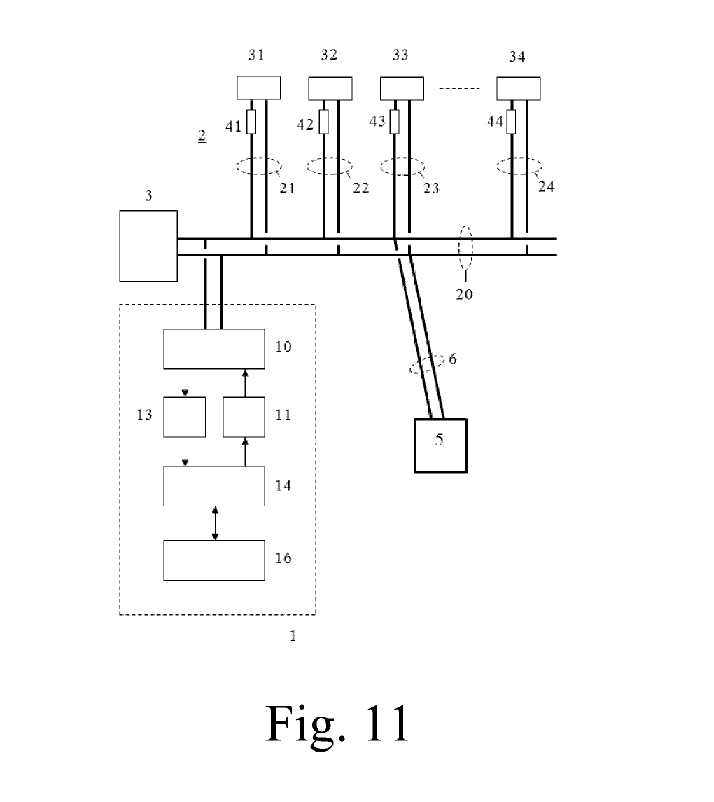

FIG. 11 shows another embodiment of the present invention to detect an illegal appliance connected the main part of the cable. In this embodiment, the loads 31-34 are street luminaires. At the luminaire side of each light pole, an inductor 41-44 is mounted to connect the branch cable 21-24 and the luminaire 31-34. The injector 11 is here in the form of a generator 11 for generating a first investigation signal in the form of a first pulse signal. Illegal access to mains cable happens when the cable system are in work, so to avoid or reduce interference to the normal work, preferrably, the first pulse signal is injected to the main cable through a capacitor. Once the injected pulse arrives at each luminaire, the inductor will cause a positive reflection and propagates back to the source 3. In the device 1, the receiver 13, e.g, a voltage sensor and the processor 14, e.g. a micro controller record the received voltage wave as reference. Once there is an illegal power access, e.g. the appliance 5 connected to the main cable 20 through cable 6, that appliance 5 will also cause reflection to the injected pulse. Then, the processor 14 can compare the received wave in this case with the recorded reference, find the starting point of the difference, and figure out the position of the illegal accessing appliance 5. Suppose the wave speed of the narrow pulse in the mains is v, the time moment of injecting the pulse is t₀, and the time moment of the starting point of the difference is t₁, we can easily figure out the position of the illegal accessing point is v(t₁−t₀)/2. Since the existing of inductors, the status of each luminaire (31-34) will not influence the reflection. Besides, the inductor with proper impedance can match the cable impedance. Then it will not cause reflection, and in the device 1, the received signal will be more simple, which is helpful for signal processing in the cabinet.

It is to be noted that the inductors 41-44 are optional in case of detection of illegal access appliance 5 and its position. The purpose of inserting inductors 41-44 are to increase ratio of useful signals in the received reflection signal. The inductors 41-44 could be intergrated into luminaires 31-34. The inductors 41-44 could be also inserted at the bottom of brance cables 21-24 to further reduce reflection from brance cables.

First and second units can be coupled directly without a third element being in between or can be coupled indirectly with a third unit being in between. The device 1 may be a solitary device or may form part of a collection system further comprising the cable 20-24 or one or more of the loads 31-34 or the source 3. Preferably, a branch part 21-24 should have a length smaller than a distance between connections between a main part 20 and two subsequent branch parts 21-24.

Summarizing, devices 1 for detecting problems in cable systems 2 comprising cables 20-24 and loads 31-34 are provided with injectors 11, 12 for injecting first investigation signals into the cables 20-24, receivers 13 for receiving first reflection signals comprising first reflections of the first investigation signals from the cables 20-24, and processors 14. The processors 14 convert the first reflection signals into reflection values and determine differences between the reflection values and reference values. A firstly occurring significant difference of the differences is indicative for the problem, and a moment in time of the firstly occurring significant difference is indicative for a location of the problem. Previously received reflection signals comprising reflections from previously injected investigation signals that have been injected at moments in time at which there were no problems in the cable system 2 may be converted into the reference values.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A device (1) for detecting a problem in a cable system (2) comprising a cable (20-24) and a plurality of loads (31-34) coupled to the cable (20-24), the device (1) comprising
an injector (11, 12) for injecting a first investigation signal into the cable (20-24),
a receiver (13) for receiving a first reflection signal from the cable (20-24), the first reflection signal comprising first reflections of the first investigation signal, and
a processor (14) for converting the first reflection signal into reflection values and for determining differences between the reflection values and reference values, a firstly occurring difference of the differences when being equal to or larger than a threshold value being indicative for the problem, and a moment in time of the firstly occurring difference being indicative for a location of the problem,
wherein the processor (14) is arranged to convert a previously received reflection signal comprising reflections from a previously injected investigation signal that has been injected at a moment in time at which there was no problem in the cable system (2) into the reference values.

2. The device (1) as defined in claim 1, the injector (11, 12) being arranged to inject a second investigation signal after the first investigation signal into the cable (20-24), the receiver (13) being arranged to receive a second reflection signal from the cable (20-24), the second reflection signal comprising second reflections of the second investigation signal, the processor (14) being arranged to convert the second reflection signal into the reflection values, and the processor (14) being arranged to convert previously received reflection signals comprising reflections from previously injected investigation signals that have been injected at moments in time at which there were no problems in the cable system (2) into the reference values.

3. The device (1) as defined in claim 1, the processor (14) being arranged to determine the differences between the reflection values and the reference values by inserting one or more reflection values into a first function and calculating a first result and inserting one or more reference values into a second function and calculating a second result and by comparing the first and second results with each other.

4. The device (1) as defined in claim 1, the processor (14) being arranged to determine the differences between the reflection values and the reference values by inserting one or more reflection values and one or more reference values into a third function and calculating a third result and by comparing the third result with the threshold value.

5. The device (1) as defined in claim 1, the injector (11, 12) comprising a generator (11) for generating a first pulse signal, the first investigation signal comprising the first pulse signal.

6. The device (1) as defined in claim 1, the injector (11, 12) comprising a switch (12) for switching a feeding signal for feeding the loads (31-33) via the cable (20-23).

7. The device (1) as defined in claim 7, further comprising
a controller (15) for detecting a phase-angle of the feeding signal and for in response to a detection result controlling the switch (12) for switching-off the feeding signal at a pre-defined phase angle of the feeding signal.

8. The device (1) as defined in claim 7, further comprising
a controller (15) for controlling the switch (12) for interrupting the feeding signal for a first time-interval shorter than 0.1 second.

9. The device (1) as defined in claim 1, wherein the cable system (2) further comprises a temporarily connected illegal appliance (5) via a cable (6) to the main cable system (2), and the processor (14) is further arranged to detect the position of the illegal appliance (5).

10. The device (1) as defined in claim 9, wherein the cable system (2) further comprises inductors (41-44) connected between the loads (31-34) and the cables (20-24).

11. A collection system comprising the device (1) as defined in claim 1 and further comprising a cable (20-24) and/or a load (31-34) and/or a source (3).

12. The collection system as defined in claim 11 comprising the load (31-34) in the form of a lamp.

13. A method for detecting a problem in a cable system (2) comprising a cable (20-24) and a plurality of loads (31-34) coupled to the cable (20-24), a first investigation signal being injected into the cable (20-24), a first reflection signal being received from the cable (20-24), the first reflection signal comprising first reflections of the first investigation signal, the method comprising a step of converting the first reflection signal into reflection values and a step of determining differences between the reflection values and reference values, a firstly occurring difference of the differences when being equal to or larger than a threshold value being indicative for the problem, and a moment in time of the firstly occurring difference being indicative for a location of the problem, wherein the reference values are converted from a previously received reflection signal comprising reflections from a previously injected investigation signal that has been injected at a moment in time at which there was no problem in the cable system (2).

14. A computer program product for performing the steps of the method as defined in claim 13.

15. A medium for storing and comprising the computer program product as defined in claim 14.
